(19) United States
(12) Patent Application Publication
(10) Pub. No.: US 2026/0305437 A1
(43) Pub. Date: Oct. 1, 2026

(54) MOUNTING DEVICE AND METHOD FOR DETECTING DISPLACEMENT

(71) Applicant: Yamaha Robotics Co., Ltd., Tokyo (JP)

(72) Inventors: Yuji Eguchi, Tokyo (JP); Kohei Seyama, Tokyo (JP)

(73) Assignee: Yamaha Robotics Co., Ltd., Tokyo (JP)

(21) Appl. No.: 19/490,954

(22) PCT Filed: Apr. 3, 2024
(86) PCT No.: PCT/JP2024/013726

§ 371 Date: Dec. 8, 2025

(30) Foreign Application Priority Data
Jun. 9, 2023 (JP) 2023-095395

(51) Int. Cl. H10W 72/00

(52) U.S. Cl. CPC H10W 72/07178; H10W 72/073

(57) ABSTRACT

A mounting device includes: a bonding head having a cylindrical side surface; a support member supporting the bonding head; a first actuator causing the bonding head to advance and retreat in an axial direction thereof; a second actuator causing the bonding head to rotate around an axis thereof; a first scale provided on the cylindrical side surface for detecting displacement of the bonding head in the axial direction; a second scale provided on the cylindrical side surface for detecting displacement of the bonding head around the axis; a first sensor head which reads the first scale and outputs a first detection signal corresponding to displacement of the bonding head in the axial direction; and a second sensor head supported by the support member that reads the second scale and outputs a second detection signal corresponding to displacement of the bonding head around the axis.

### TECHNICAL FIELD

The present invention relates to a mounting device and a method for detecting displacement of a bonding head provided to the mounting device.

### DESCRIPTION OF RELATED ART

For example, in mounting devices used during semiconductor chip manufacturing such as die bonders, it is needed to control the position of a bonding head that has adsorbed a semiconductor chip at a tip part thereof and accurately place the semiconductor chip on a die pad of a lead frame disposed on a stage. For this purpose, technologies for precisely measuring the position of the bonding head or the adsorbed semiconductor chip relative to the die pad have been proposed (for example, see Patent Document 1).

### RELATED ART

### Patent Documents

Patent Document 1: Japanese Patent Application Laid-Open No. 2014-036068

### SUMMARY

### Technical Problem

Even if the relative positional relationship immediately before placing a semiconductor chip on a lead frame can be accurately measured, the semiconductor chip is unable to be correctly placed at the target position on the lead frame unless the bonding head that adsorbs the semiconductor chip can be displaced with high precision. In particular, in the stage immediately before placing the semiconductor chip on the lead frame, in the case of directly driving and displacing the bonding head, it is particularly desirable to detect the displacement amount with high precision. Such requirements are the same even for a flip chip bonder that mounts a semiconductor chip at a target position on a substrate.

In general mounting devices, the bonding head is rotated via a link mechanism or gear train, so the output shaft of the actuator and the rotation axis of the bonding head do not coincide. Additionally, the drive mechanism that causes the bonding head to move linearly and the drive mechanism that causes the bonding head to rotate may be hierarchically structured in a stacked manner relative to the bonding head. Therefore, in the case of attempting to calculate the rotation amount of the bonding head by detecting the rotation amount of the output shaft of the actuator, accurate values could not always be obtained due to play in the power transmission mechanism, cumulative errors from the hierarchical structure, and the like.

The present invention has been made to solve such problems, and provides a mounting device, etc. that can accurately detect the displacement amount in the advancing/retreating direction and the displacement amount in the rotation direction of the bonding head.

### Solution to the Problem

A mounting device according to a first aspect of the present invention includes: a bonding head having a cylindrical side surface; a support member which supports the bonding head so as to be capable of advancing and retreating in an axial direction along a central axis of the cylindrical side surface and rotating around the central axis; a first actuator which causes the bonding head to advance and retreat in the axial direction; a second actuator which has an output shaft that does not coincide with the central axis and which causes the bonding head to rotate around the axis; a first scale provided on the cylindrical side surface for detecting displacement of the bonding head in the axial direction; a second scale provided on the cylindrical side surface for detecting displacement of the bonding head around the axis; a first sensor head which reads the first scale and outputs a first detection signal corresponding to displacement of the bonding head in the axial direction; and a second sensor head supported by the support member that reads the second scale and outputs a second detection signal corresponding to displacement of the bonding head around the axis.

Further, a method for detecting displacement according to a second aspect of the present invention is a method for detecting displacement of a bonding head provided to a mounting device, and the method for detecting displacement includes: a second output step in which when the bonding head having a cylindrical side surface is displaced relative to a support member that supports the bonding head by using a second actuator having an output shaft that does not coincide with a central axis of the cylindrical side surface around the central axis, a second sensor head supported by the support member reads a second scale provided on the cylindrical side surface and outputs a second detection signal corresponding to displacement of the bonding head around the axis; and a first output step in which when the bonding head is displaced relative to the support member in an axial direction along the central axis by using a first actuator, a first sensor head reads a first scale provided on the cylindrical side surface and outputs a first detection signal corresponding to displacement of the bonding head in the axial direction.

### Effects

The present invention can provide a mounting device, etc. that can accurately detect the displacement amount in the advancing/retreating direction and the displacement amount in the rotation direction of the bonding head.

### BRIEF DESCRIPTION OF THE DRAWINGS

FIG. 1 is a perspective view schematically showing main parts of a flip chip bonder according to the embodiment.

FIG. 2 is a system configuration diagram of the flip chip bonder.

FIG. 3 is a perspective view schematically showing a bonding head and two sensor heads.

FIG. 4 is a diagram schematically showing a scale film.

FIG. 5 is a flow diagram describing a processing procedure of an arithmetic processing part in the case of directly displacing the bonding head.

### DESCRIPTION OF EMBODIMENTS

The present invention will be described through embodiments of the invention below, but the invention according to the claims is not limited to the following embodiments. Additionally, not all of the configurations described in the embodiments are necessarily essential as means for solving the problems.

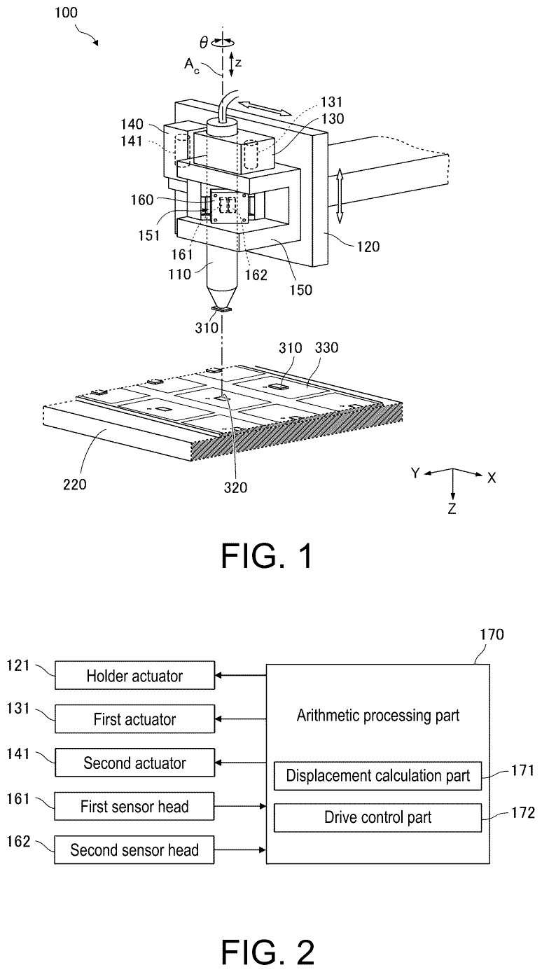

FIG. 1 is a perspective view schematically showing main parts of a flip chip bonder 100 according to the embodiment. The flip chip bonder 100 is an example of a mounting device incorporating a position control device, and is a bonding device that mounts a semiconductor chip 310 having an electrode formed on one surface thereof to an electrode of a substrate 330. Note that the perspective view of the flip chip bonder 100 shown in FIG. 1 is a diagram that limitedly and schematically shows elements related to position control in the case of directly displacing a bonding head 110, and does not show all configurations essential for the flip chip bonder 100 to exhibit functions thereof. Further, the mounting device is not limited to a flip chip bonder, and may be a die bonder that places and bonds a semiconductor chip on a die pad of a lead frame.

The flip chip bonder 100 mainly includes a bonding head 110, a holder base 120, a linear motion mechanism part 130, a rotation mechanism part 140, a holder block 150, and a sensor plate 160. The bonding head 110 adsorbs the semiconductor chip 310 at a tip part, places the semiconductor chip 310 on a mounting area 320 of the substrate 330 placed on a stage 220, and bonds the semiconductor chip 310 by applying pressure and heat. The bonding head 110 in the embodiment has an overall cylindrical shape, and a central axis Ac thereof on a cylindrical side surface is parallel to a Z axis as illustrated. In the embodiment, a Z-axis direction is the vertical direction (height direction) as illustrated, and an X-axis direction and a Y-axis direction are planar directions that are defined to be orthogonal to each other.

The holder base 120 is a support member that supports the bonding head 110 via the holder block 150. The holder base 120 also supports the linear motion mechanism part 130 and the rotation mechanism part 140 directly or indirectly. Additionally, the holder base 120 can be moved as a whole in the space above the stage 220 in the vertical direction and planar direction as shown by the outlined arrows in the drawing by driving a holder actuator (not shown in FIG. 1). Through such overall movement control, the holder base 120 can, for example, move the bonding head 110 that has adsorbed the semiconductor chip 310 with a chip supply device to above the mounting area 320 that serves as the placement target. It is preferable that the bonding head 110 maintains a stationary state relative to the holder base 120 during the overall movement of the holder base 120.

The linear motion mechanism part 130 is an advance/retreat fine movement mechanism for advancing and retreating the bonding head 110 within a range of minute distances (for example, ±0.5 mm with respect to a reference position) set in an axial direction along the central axis A_{c} (z direction shown by arrows in the figure). The linear motion mechanism part 130 includes, for example, a first actuator 131 that is a motor, and a transmission mechanism that transmits the output of the first actuator 131. The transmission mechanism is configured by, for example, a gear train including a rack and pinion gear.

The rotation mechanism part 140 is a rotation fine movement mechanism for rotating the bonding head 110 around the central axis A_{c} (θ direction shown by arrows in the figure) within a range of minute angles (for example, ±5 degrees with respect to a reference angle). The rotation mechanism part 140 includes, for example, a second actuator 141 that is a motor, and a transmission mechanism that transmits the output of the second actuator 141. The transmission mechanism is configured by, for example, a lever crank mechanism and a gear train. The first actuator 131 and the second actuator 141 may drive the bonding head 110 in the axial direction or around the axis by a voice coil motor, air cylinder, hydraulic cylinder, linear motor, or the like that omits the transmission mechanism.

The holder block 150 is a guide member that is attached to the holder base 120 and supports and guides the bonding head 110 such that the bonding head 110 can advance and retreat in the axial direction along the central axis A_{c} and can rotate around the axis of the central axis A_{c}. The holder block 150 may be formed integrally with the holder base 120. The holder block 150 has an opening window 151 for exposing a part of the cylindrical side surface of the bonding head 110 to the outside. The opening window 151 has a shape surrounded by a rectangular frame in FIG. 1, but may have any shape as long as the holder block 150 maintains the function of supporting and guiding the bonding head 110.

The sensor plate 160 is a plate-shaped member that faces the cylindrical side surface of the bonding head 110 and is disposed on the holder block 150 so as to cover at least a part of the opening window 151. The sensor plate 160 supports a first sensor head 161 and a second sensor head 162 such that respective sensing parts thereof face the cylindrical side surface of the bonding head 110. The first sensor head 161 outputs a first detection signal corresponding to displacement of the bonding head 110 in the axial direction (advancing/retreating direction). The second sensor head 162 outputs a second detection signal corresponding to displacement of the bonding head 110 around the axis (rotation direction). In FIG. 1, the first sensor head 161 and the second sensor head 162 are supported by the sensor plate 160 so as to protrude toward the inside of the opening window 151.

By arranging the first sensor head 161 and the second sensor head 162 on the sensor plate 160 in this manner, a displacement calculation part described later can calculate a displacement amount in the axial direction and a displacement amount around the axis of the bonding head 110 relative to the holder base 120. That is, the first sensor head 161 and the second sensor head 162 can be said to be substantially supported by the holder base 120.

FIG. 2 is a system configuration diagram of the flip chip bonder 100. A control system of the flip chip bonder 100 is mainly configured by an arithmetic processing part 170, a holder actuator 121, the first actuator 131, the second actuator 141, the first sensor head 161, and the second sensor head 162. The arithmetic processing part 170 is a processor (Central Processing Unit, CPU) that performs control of the flip chip bonder 100 and program execution processing. The processor may be configured to cooperate with an arithmetic processing chip such as an Application Specific Integrated Circuit (ASIC) or Graphics Processing Unit (GPU).

The arithmetic processing part 170 also serves as a functional arithmetic unit that executes various calculations according to processing instructed by a position control program. Specifically, the arithmetic processing part 170 may function as a displacement calculation part 171 and a drive control part 172. The displacement calculation part 171 receives a first detection signal output by the first sensor head 161, and processes the first detection signal to calculate an axial direction (advancing/retreating direction) displacement amount of the bonding head 110 relative to the holder base 120. Additionally, the displacement calculation part 171 receives a second detection signal output by the second sensor head 162, and processes the second detection signal to calculate a displacement amount around the axis (rotation direction) of the bonding head 110 relative to the holder base 120. Furthermore, the displacement calculation part 171 receives a position detection signal from a position sensor (not shown), and processes the position detection signal to calculate three-dimensional coordinates at a reference position of the holder base 120.

In fine movement control, the drive control part 172 determines an advance/retreat target amount by which the semiconductor chip 310 should be displaced to reach the mounting area 320 that is the placement target of the semiconductor chip 310, and also determines a rotation target amount by which the semiconductor chip 310 should be displaced to be placed in the mounting area 320 in a correct posture. Then, the drive control part 172 adjusts the semiconductor chip 310 to a target posture by transmitting a drive signal to the second actuator 141 while sequentially comparing the rotation target amount with the displacement amount around the axis calculated by the displacement calculation part 171. Furthermore, the drive control part 172 places the semiconductor chip 310 at a target position in the mounting area 320 by transmitting a drive signal to the first actuator 131 while sequentially comparing the advance/retreat target amount with the displacement amount in the axial direction calculated by the displacement calculation part 171. Also, in overall movement control, the drive control part 172 determines a movement target position of the holder base 120. Then, the drive control part 172 causes the holder base 120 to reach the movement target position by transmitting a drive signal to the holder actuator 121 while sequentially comparing the movement target position with the three dimensional coordinates of the holder base 120 calculated by the displacement calculation part 171.

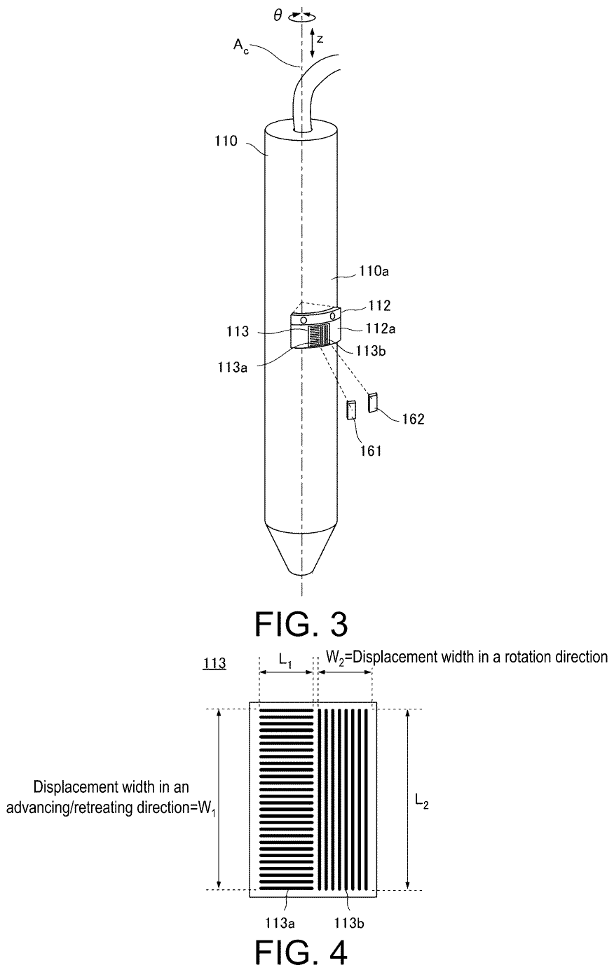

Next, the displacement detection sensor employed in the embodiment and the arrangement thereof will be described. FIG. 3 is a perspective view schematically showing the bonding head 110 and two sensor heads (first sensor head 161, second sensor head 162). In FIG. 3, the two sensor heads are drawn with greater separation than in reality and with the sensor plate 160 that supports the sensor heads omitted, so that the relationship between each of the sensor heads and an opposing scale film 113 can be easily understood.

The first sensor head 161, paired with a first scale 113a drawn on the opposing scale film 113, constitutes a z-axis encoder that detects an axial direction (advancing/retreating direction) displacement amount of the central axis A_{c} of the bonding head 110. The z-axis encoder is a reflective linear encoder that receives, with a photodiode, reflected light that is projection light emitted from the first sensor head 161 and reflected by the first scale 113a, and outputs a first detection signal corresponding to displacement in the axial direction, which is generated based on the intensity of the reflected light.

The second sensor head 162, paired with a second scale 113b drawn on the opposing scale film 113, constitutes a θ-axis encoder that detects a displacement amount around the axis (rotation direction) of the central axis A_{c} of the bonding head 110. The θ-axis encoder is a reflective linear encoder that receives, with a photodiode, reflected light that is projection light emitted from the second sensor head 162 and reflected by the second scale 113b, and outputs a second detection signal corresponding to displacement around the axis, which is generated based on the intensity of the reflected light. In the embodiment, both the z-axis encoder and the θ-axis encoder employ such reflective linear encoders, but any type of sensor may be employed as long as the sensor is a displacement sensor that outputs a detection signal corresponding to displacement by positioning the scale and sensor head in opposition to each other. For example, a magnetic encoder may be employed in which the scale is configured with a magnet and the change thereof is detected by a magnetic sensor provided in the sensor head.

At least a part of a side surface of the bonding head 110 is configured by a cylindrical side surface 110a formed by an arc equidistant from the central axis A_{c}. The scale film 113 may be directly adhered to the cylindrical side surface 110a, but in the embodiment, the scale film 113 is indirectly mounted via the scale block 112 in consideration of ease of mounting.

The scale block 112 has an outer surface 112a that forms an arc surface equidistant from the central axis A_{c} in the case of being attached to the bonding head 110, and substantially becomes the cylindrical side surface of the bonding head 110. The scale film 113 is adhered to the outer surface 112a. Therefore, in response to the scale block 112 being attached to the bonding head 110, the scale film 113 adhered to the outer surface 112a is substantially provided on the cylindrical side surface of the bonding head 110. That is, the first sensor head 161 can directly detect displacement of the bonding head 110 in the advancing/retreating direction by reading changes in the first scale 113a, and the second sensor head 162 can directly detect displacement of the bonding head 110 in the rotation direction by reading changes in the second scale 113b. Note that even in the case of the bonding head 110 not having a cylindrical side surface, or even in the case of having a cylindrical side surface but the scale block 112 not being mounted on the cylindrical side surface, according to the outer surface 112a of the scale block 112 mounted on the bonding head 110 being an arc surface equidistant from the central axis A_{c} that serves as the rotation axis of the bonding head 110, the bonding head 110 substantially has a cylindrical side surface, and the scale film 113 may be adhered to the outer surface 112a.

In a mounting device, it is difficult to directly rotate the bonding head by aligning the output shaft of the actuator for rotation (the second actuator 141 in the embodiment) with the central axis of the bonding head. In actual design, as in the embodiment, the bonding head is often rotated by combining an actuator having an output shaft that does not coincide with the central axis A_{c} of the bonding head and a transmission mechanism that transmits the output thereof. In the case of such a configuration, in conventional mounting devices, the rotation amount of the output shaft of the actuator was detected by a rotary encoder, and the rotation amount of the bonding head was calculated by using a conversion formula. However, in the case of calculating the rotation amount of the bonding head in this manner, accurate values could not necessarily be obtained due to play in the transmission mechanism and mounting errors. There have been attempts to fix the actuator to the linear motion mechanism part and align the output shaft thereof with the central axis of the bonding head, but in the case of such a configuration, since the rotation mechanism part is structured to be stacked on the linear motion mechanism part, errors accompanying the operation of the linear motion mechanism part are also accumulated, and accurate rotation amount of the bonding head could not be obtained.

According to the flip chip bonder 100 of the embodiment in contrast to such conventional technology, both the first sensor head 161 and the second sensor head 162 are substantially supported by the holder base 120 without a drive mechanism part interposed therebetween, and both the first scale 113a and the second scale 113b are substantially adhered to the cylindrical side surface of the bonding head 110. Therefore, both the displacement in the axial direction and the displacement around the axis of the bonding head 110 can be directly detected, and each of the displacement amounts can be obtained with higher accuracy compared to conventional mounting devices. In the embodiment, the displacement calculation part 171 calculates the displacement amount in the axial direction and the displacement amount around the axis based on the first detection signal and the second detection signal, but by observing changes in each of the detection signals per short time period, the axial direction velocity and angular velocity around the axis of the bonding head 110 may also be calculated.

FIG. 4 is a diagram schematically showing the scale film 113. In the embodiment, the first scale 113a and the second scale 113b are drawn adjacently on a single film. Since the first scale 113a is a scale for detecting axial displacement of the bonding head 110, first line segments having a length L₁ orthogonal to the axial direction (advancing/retreating direction) are arranged for the number of pieces corresponding to the set resolution and a displacement width W₁ in the advancing/retreating direction. The displacement width W₁ is 1.0 mm in the case of ±0.5 mm with respect to the reference position as described above.

Since the second scale 113b is a scale for detecting displacement around the axis of the bonding head 110, second line segments having a length L₂ orthogonal to the axial direction (rotation direction) are arranged for the number of pieces corresponding to the set resolution and a displacement width W₂ in the rotation direction. The displacement width W₂ is 2π×8×10/360 mm in the case where the curvature radius of the outer surface 112a, which is the adhesion surface of the scale film 113, is, for example, 8 mm, and the rotation angle is, for example, ±5 degrees with respect to the reference angle as described above.

Here, in the case where the first scale 113a and the second scale 113b are disposed adjacent to each other, in order for the second sensor head 162 to detect the displacement amount according to rotation of the bonding head 110, regardless of where the projection light emitted from the first sensor head 161 is emitted within the displacement width W₁, the length L₂ of the second line segment needs to have a length equal to or greater than the displacement width W₁. Similarly, in order for the first sensor head 161 to detect the displacement amount according to advancing/retreating of the bonding head 110, regardless of where the projection light emitted from the second sensor head 162 is emitted within the displacement width W₂, the length L₁ of the first line segment needs to have a length equal to or greater than the displacement width W₂. In the embodiment, from the viewpoint of making the scale film 113 as small as possible, L₁=W₂ and L₂=W₁ are set. That is, the length L₁ of each of the first line segments is equal to an interval W₂ between the line segments at both ends among the second line segments, and the length L₂ of each of the second line segments is equal to an interval W₁ between the line segments at both ends among the first line segments.

In the embodiment, the first scale 113a and the second scale 113b are arranged side by side on a single film in order to draw the first line segment and the second line segment orthogonally to each other with high accuracy, but the disposition of the first scale 113a and the second scale 113b is not limited to the example. The first scale 113a and the second scale 113b may be formed separately and adhered to the outer surface 112a or the cylindrical side surface 110a with orientations thereof adjusted relative to each other. Additionally, in cases where the first sensor head 161 and the second sensor head 162 are each supported by separate support members, the first scale 113a and the second scale 113b may be disposed separately so as to face respective sensor head positions thereof.

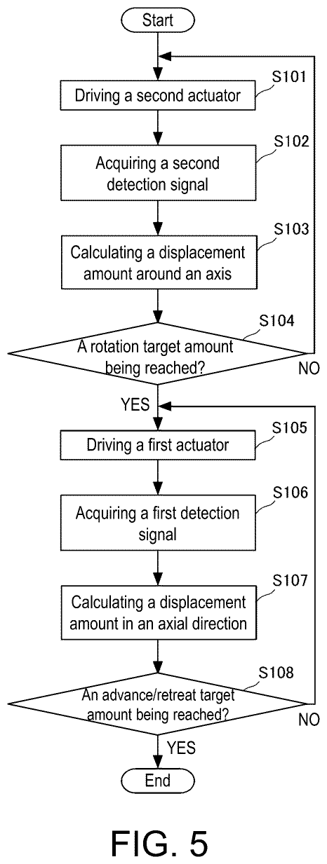

Next, a processing procedure of the arithmetic processing part in the case of directly displacing the bonding head 110 will be described. FIG. 5 is a flow diagram describing the processing procedure. The illustrated flow starts from a point where the bonding head 110 is moved to above the mounting area 320 that serves as the placement target by overall movement control, and the advance/retreat target amount and rotation target amount of the bonding head 110 thereafter are determined.

The drive control part 172 transmits a drive signal to the second actuator 141 in step S101 to rotate the bonding head 110. The displacement calculation part 171 acquires a second detection signal output by the second sensor head 162 reading the second scale 113b in step S102, and calculates the displacement amount around the axis from the second detection signal in step S103.

The displacement calculation part 171 determines in step S104 whether the calculated displacement amount has reached the determined rotation target amount. In the case of determining that the rotation target amount has not been reached, the process returns to step S101. In the case of determining that the rotation target amount has been reached, the displacement calculation part 171 causes the drive control part 172 to stop transmission of the drive signal to the second actuator 141 and proceeds to step S105.

The drive control part 172 transmits a drive signal to the first actuator 131 in step S105 to advance and retreat the bonding head 110. The displacement calculation part 171 acquires a first detection signal output by the first sensor head 161 reading the first scale 113a in step S106, and calculates the displacement amount in the axial direction from the first detection signal in step S107.

The displacement calculation part 171 determines in step S108 whether the calculated displacement amount has reached the determined advance/retreat target amount. In the case of determining that the advance/retreat target amount has not been reached, the process returns to step S105. In the case of determining that the advance/retreat target amount has been reached, the displacement calculation part 171 causes the drive control part 172 to stop transmission of the drive signal to the first actuator 131, and ends the process of placing the semiconductor chip 310 onto the mounting area 320 that serves as the placement target.

### REFERENCE SIGNS LIST

100 . . . flip chip bonder, 110 . . . bonding head, 110a . . . cylindrical side surface, 112 . . . scale block, 112a . . . outer surface, 113 . . . scale film, 113a . . . first scale, 113b . . . second scale, 120 . . . holder base, 121 . . . holder actuator, 130 . . . linear motion mechanism part, 131 . . . first actuator, 140 . . . rotation mechanism part, 141 . . . second actuator, 150 . . . holder block, 151 . . . opening window, 160 . . . sensor plate, 161 . . . first sensor head, 162 . . . second sensor head, 170 . . . arithmetic processing part, 171 . . . displacement calculation part, 172 . . . drive control part, 220 . . . stage, 310 . . . semiconductor chip, 320 . . . mounting area, 330 . . . lead frame

1. A mounting device, comprising:
a bonding head, having a cylindrical side surface;
a support member, supporting the bonding head so as to be capable of advancing and retreating in an axial direction along a central axis of the cylindrical side surface and capable of rotating around the central axis;
a first actuator, causing the bonding head to advance and retreat in the axial direction;
a second actuator, having an output shaft that does not coincide with the central axis and causing the bonding head to rotate around the axis;
a first scale, provided on the cylindrical side surface for detecting displacement of the bonding head in the axial direction;
a second scale, provided on the cylindrical side surface for detecting displacement of the bonding head around the axis;
a first sensor head, reading the first scale and outputting a first detection signal corresponding to displacement of the bonding head in the axial direction; and
a second sensor head supported by the support member, reading the second scale and outputting a second detection signal corresponding to displacement of the bonding head around the axis.

2. The mounting device according to claim 1, wherein the first scale and the second scale are disposed adjacent to each other on the cylindrical side surface.

3. The mounting device according to claim 2, wherein
the first scale is formed by a plurality of first line segments,
the second scale is formed by a plurality of second line segments,
a length of each of the plurality of first line segments is equal to an interval between line segments at both ends among the plurality of second line segments, and a length of each of the plurality of second line segments is equal to an interval between line segments at both ends among the plurality of first line segments.

4. The mounting device according to claim 2, wherein the first scale and the second scale are integrally formed and mounted on the cylindrical side surface.

5. A method for detecting displacement which is a method for detecting displacement of a bonding head provided to a mounting device, the method for detecting displacement comprising:
a second output step, when the bonding head having a cylindrical side surface is displaced relative to a support member that supports the bonding head by using a second actuator having an output shaft that does not coincide with a central axis of the cylindrical side surface around the central axis, a second sensor head supported by the support member reading a second scale provided on the cylindrical side surface and outputting a second detection signal corresponding to displacement of the bonding head around the axis; and
a first output step, when the bonding head is displaced relative to the support member in an axial direction along the central axis by using a first actuator, a first sensor head reading a first scale provided on the cylindrical side surface and outputting a first detection signal corresponding to displacement of the bonding head in the axial direction.

6. The mounting device according to claim 3, wherein the first scale and the second scale are integrally formed and mounted on the cylindrical side surface.
